(19) United States
(12) Patent Application Publication
(10) Pub. No.: US 2026/0177927 A1
(43) Pub. Date: Jun. 25, 2026

(54) EXPOSURE APPARATUS, EXPOSURE METHOD, AND ARTICLE MANUFACTURING METHOD

(71) Applicant: CANON KABUSHIKI KAISHA, Tokyo (JP)

(72) Inventor: TADASHI ARAI, Tochigi (JP)

(21) Appl. No.: 19/416,525

(22) Filed: Dec. 11, 2025

(30) Foreign Application Priority Data
Dec. 20, 2024 (JP) 2024-225567

(51) Int. Cl. G03F 7/00

(52) U.S. Cl. CPC G03F 7/70258

(57) ABSTRACT

An exposure apparatus that transfers a pattern of an original to a substrate is provided. The apparatus include a shutter configured to switch blocking and passing of an optical path of exposure light by operating a plurality of light shielding members, a projection optical system configured to project a pattern of the original onto the substrate by the exposure light, and an adjuster configured to adjust a defocus amount which represents a distance between a best focus position in a direction of an optical axis of the projection optical system and a position of a surface of the substrate. The plurality of light shielding members have rotational symmetricity with respect to the optical axis.

### BACKGROUND

### Field of the Technology

The present disclosure relates to an exposure apparatus, an exposure method, and an article manufacturing method.

### Description of the Related Art

As the products manufactured by an exposure apparatus become more diverse, the exposure apparatus needs to support various processes. One solution to this is a thick-film resist. When exposing a thick-film resist, a problem can arise that a general exposure method does not provide sufficient depth of focus. To solve this problem, multi-focus exposure is known in which, in a stepper method in which an original (reticle) is fixed during exposure, exposure is performed a plurality of times while moving a substrate in the optical axis direction of a projection optical system, that is, while changing the focal distance (for example, see Japanese Patent Laid-Open No. 02-137216).

Conventionally, the exposure shutter in the exposure apparatus adopts a rotational driving method in which the exposure shutter is opened and closed by rotating a light shielding member (shutter blade) in a direction crossing the optical path of exposure light. This is advantageous in terms of high speed.

However, when the exposure shutter adopting the rotational driving method is applied to the multi-focus exposure technique, an asymmetric defect of the effective light source due to rotational driving, combined with substrate driving in the height direction (the optical axis direction of the projection optical system) for multi-focus exposure, can cause a noticeable loss of telecentricity.

### SUMMARY

The present disclosure provides a technique advantageous in suppressing occurrence of asymmetry in an effective light source.

The present disclosure in its one aspect provides an exposure apparatus that transfers a pattern of an original to a substrate, including a shutter configured to switch blocking and passing of an optical path of exposure light by operating a plurality of light shielding members, a projection optical system configured to project a pattern of the original onto the substrate by the exposure light, and an adjuster configured to adjust a defocus amount which represents a distance between a best focus position in a direction of an optical axis of the projection optical system and a position of a surface of the substrate, wherein the plurality of light shielding members have rotational symmetricity with respect to the optical axis.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view showing the arrangement of an exposure apparatus;

FIGS. 2A and 2B are views for explaining the problem of a conventional technique;

FIGS. 3A and 3B are views showing the arrangement of an exposure shutter according to an embodiment;

FIG. 4A is a view showing the arrangement of the exposure shutter according to the first modification;

FIG. 4B is a view showing the arrangement of the exposure shutter according to the second modification;

FIG. 5 is a view showing the arrangement of the exposure shutter according to the third modification;

FIG. 6 is a flowchart illustrating an exposure method using multi-focus exposure; and

FIG. 7 is a timing chart of a shutter opening/closing operation in multi-focus exposure.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

### First Embodiment

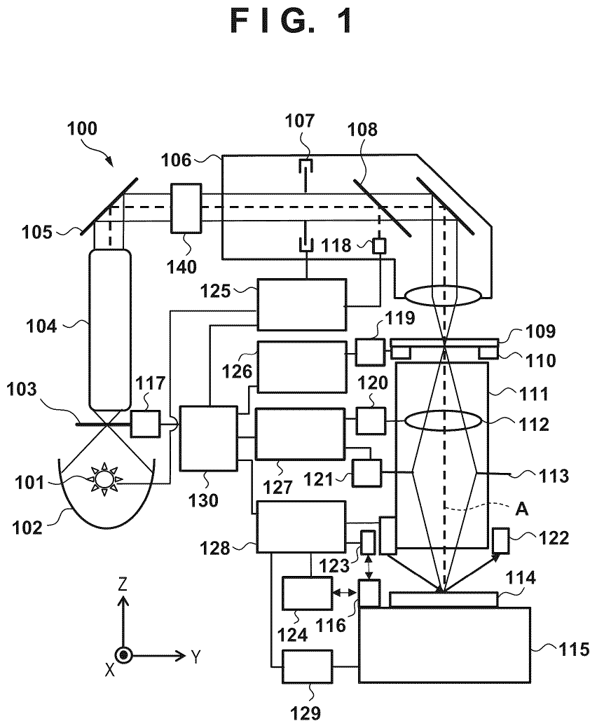

FIG. 1 is a view showing the arrangement of an exposure apparatus 100 according to an embodiment that transfers the pattern of an original to a substrate. In the specification and the drawings, directions will be indicated in an XYZ coordinate system in which the horizontal surface is set as the X-Y plane. In general, a substrate 114 as an exposure target is placed on a substrate stage 115 such that the surface of the substrate 114 becomes parallel to the horizontal surface (X-Y plane). Accordingly, in the following description, directions orthogonal to each other within a plane along the surface of the substrate 114 are respectively defined as the X-axis and the Y-axis, and a direction perpendicular to the X-axis and the Y-axis is defined as the Z-axis. In addition, in the following description, directions parallel to the X-axis, the Y-axis, and the Z-axis in the XYZ coordinate system are respectively defined as the X direction, the Y direction, and the Z direction.

A light source 101 accommodated in a light source unit 102 can emit radiation light of the far ultraviolet region, for example, having a wavelength of 365 nm. Control for wavelength stabilization in the light source 101, control of the discharge applying voltage, and the like can be performed by an illumination system controller 125.

Radiation light emitted from the light source 101 enters an optical integrator 140 via a radiation light shaping optical system 104 and a mirror 105. The radiation light shaping optical system 104 adjusts the shape and size of the light entering the optical integrator 140. The optical integrator 140 has a function of making uniform the illuminance distribution of the illuminated surface. For example, the optical integrator 140 can be formed as a fly-eye lens array. The fly-eye lens array is formed from a set of a plurality of minute lenses, and a plurality of secondary light sources are formed in the vicinity of the light emitting surface thereof. The light emitted from the optical integrator 140 is guided, via an illumination optical system 106, to an original 109 held by an original stage 110, and illuminates the original 109. The illumination optical system 106 can include an illumination light adjustment unit 107, a half mirror 108, and a light amount sensor 118. The illumination light adjustment unit 107 has a function as a wavelength selecting portion that selectively passes light of the wavelength used for exposing the substrate 114 out of the light having entered the illumination optical system 106. The illumination light adjustment unit 107 as the wavelength selecting portion can include, for example, a plurality of wavelength plates that respectively pass light components of different wavelengths. The illumination light adjustment unit 107 can selectively pass light of the wavelength used for exposing the substrate 114 by changing the wavelength plate arranged in the optical path among the plurality of wavelength plates. The plurality of wavelength plates can be arranged in, for example, a turret. The illumination light adjustment unit 107 can be controlled by the illumination system controller 125. The light beam emitted from the illumination light adjustment unit 107 is also guided to the light amount sensor 118 via the half mirror 108. The detection result of the light amount sensor 118 can be provided to a main controller 130 via the illumination system controller 125. In addition, the illumination system controller 125 can control the illumination light adjustment unit 107 in accordance with the desirable effective light source distribution designated by the main controller 130. Note that the “effective light source distribution” indicates the light intensity distribution in the pupil plane of the illumination optical system that illuminates the original.

For example, the circuit pattern of a semiconductor device is formed in the original 109. The original stage 110 holding the original 109 can be controlled by an original stage driving unit 119 via an original stage controller 126.

A projection optical system 111 guides the exposure light having passed through the original 109 to the substrate 114 placed on the substrate stage 115. Thus, the image of the pattern of the original 109 is formed and projected onto the substrate 114 (one shot region thereof) coated with a photoresist. A field lens 112 is provided in the projection optical system 111. A lens driving unit 120 can move the field lens 112 in the direction of the optical axis (optical axis direction). By a projection system controller 127 controlling the position of the field lens 112 in the optical axis direction via the lens driving unit 120, various types of aberrations of the projection optical system 111 can be suppressed. The projection optical system 111 also includes an aperture unit 113 for controlling the numerical aperture. An aperture driving unit 121 drives the aperture unit 113. The aperture driving unit 121 is controlled by the projection system controller 127. The projection system controller 127 issues a driving instruction to the aperture driving unit 121 to set the desirable numerical aperture designated by the main controller 130. The aperture driving unit 121 drives the aperture unit 113 in accordance with the driving instruction.

The substrate stage 115 can hold the substrate 114, and move in the optical axis direction (Z direction) of the projection optical system 111, and the X and Y directions orthogonal to each other in a plane perpendicular to the Z direction. A laser interferometer 124 can measure the position of the substrate stage 115 in the X-Y plane by measuring the distance from a moving mirror 116 fixed to the substrate stage 115. A substrate stage controller 128 moves the substrate stage 115 to a predetermined position in the X-Y plane by controlling a substrate stage driving unit 129 formed from a motor or the like based on the position of the substrate stage 115 measured by the laser interferometer 124.

A laser interferometer 123 can measure the Z-direction position of the substrate stage 115 by measuring the distance from the moving mirror 116. The substrate stage controller 128 can move the substrate stage 115 in the Z direction by controlling the substrate stage driving unit 129 based on the Z-direction position of the substrate stage 115 measured by the laser interferometer 123.

A focus unit 122 has a focus plane detection function. The focus unit 122 emits, via the projection optical system 111, a plurality of light beams formed from non-exposure light that does not sensitize the photoresist on the substrate 114. These light beams are respectively condensed and reflected on the substrate 114, and enter a detection optical system of the focus unit 122. In the detection optical system, a plurality of light receiving elements for position detection are arranged so as to respectively correspond to the reflected light beams. It is configured such that the light receiving surface of each light receiving element and the reflection point of each light beam on the substrate 114 become substantially conjugate by an imaging optical system. The positional deviation of the surface of the substrate 114 in the optical axis direction of the projection optical system 111 is measured as the positional deviation of the incident light beam on the light receiving element for position detection in the focus unit 122.

The main controller 130 comprehensively controls the illumination system controller 125, the original stage controller 126, the projection system controller 127, and the substrate stage controller 128. The main controller 130 can be formed from, for example, an information processing apparatus (computer) including a processor such as a Central Processing Unit (CPU) and a storage unit such as a memory. In the exposure apparatus 100 shown in FIG. 1, various kinds of controllers (the illumination system controller 125, the original stage controller 126, the projection system controller 127, and the substrate stage controller 128) controlled by the main controller 130 are separately provided. However, the main controller 130 and each controller may be provided as one controller. The main controller 130 may be arranged in the housing of the exposure apparatus 100, or may be arranged outside the exposure apparatus 100. The main controller 130 arranged outside the exposure apparatus 100 may be implemented by, for example, a computer functioning as a control server connected to the exposure apparatus 100 via a network.

In this embodiment, an exposure shutter 103 is arranged between the light source unit 102 and the radiation light shaping optical system 104. Driving for opening/closing the exposure shutter 103 can be performed by an exposure shutter driving unit 117. The main controller 130 can control exposure/non-exposure via the exposure shutter driving unit 117.

By using the focus plane detection function of the focus unit 122 described above, the substrate stage controller 128 issues an instruction to set the substrate stage 115 at the desirable position designated by the main controller 130. The substrate stage driving unit 129 drives the substrate stage 115 in accordance with the instruction. In this manner, by driving the substrate stage 115 by the substrate stage driving unit 129, the focal distance can be changed. It is possible to continuously expose the substrate 114 at different focal positions by continuously driving the substrate stage 115 in a direction (the Z direction, which is to be referred to as the “optical axis direction” hereinafter) parallel to an optical axis A of the projection optical system 111.

Note that the focal distance may be changed by a method other than driving the substrate stage 115. For example, the focal distance can also be changed by the projection system controller 127 controlling the position of the field lens 112 in the optical axis direction via the lens driving unit 120. Alternatively, the focal distance may be changed by driving the original stage 110 holding the original 109, selecting the wavelength of exposure light, and the like. In the following description, the focal distance is changed by driving the substrate stage 115 in the Z direction.

As described above, the substrate stage driving unit 129, the original stage driving unit 119, and the lens driving unit 120 can function as an adjuster that adjusts the defocus amount which represents the distance between the best focus position in the optical axis direction of the projection optical system 111 and the position of the surface of the substrate 114.

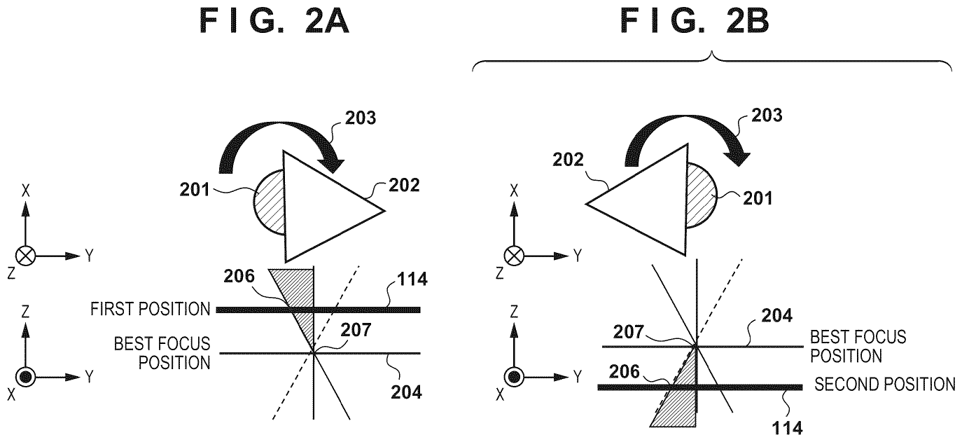

The arrangement of the exposure apparatus 100 in the embodiment is generally as described above. Next, specific problems of a conventional exposure shutter will be pointed out with reference to FIGS. 2A and 2B. Here, consider a conventional exposure shutter that switches blocking and passing of the optical path of exposure light (opens and closes the shutter) by rotating a light shielding member (shutter blade) in a direction crossing the optical path of exposure light. Assume that, to perform multi-focus exposure, the substrate 114 is driven from the first position above a best focus position 204 to the second position below the best focus position 204. FIG. 2A shows a state in which the substrate 114 is at the first position, and FIG. 2B shows a state in which the substrate 114 is at the second position. As indicated by an arrow 203, a shutter 202 is rotated clockwise. In FIG. 2A, the right side of an effective light source 201 is shielded from light when the shutter 202 is half-open. At this time, since the substrate 114 is located above the best focus position 204, an imaging position 206 is located to the left of an original imaging position 207. In FIG. 2B, the left side of the effective light source 201 is shielded from light when the shutter 202 is half-open. At this time, since the substrate 114 is located below the best focus position 204, the imaging position 206 is also located to the left of the original imaging position 207. In this manner, if the substrate 114 is at out-of-focus positions on the opposite sides sandwiching the best focus position 204 when opening and closing the shutter 202, the imaging position changes, and an image shift and a horizontal (vertical) line width difference can occur.

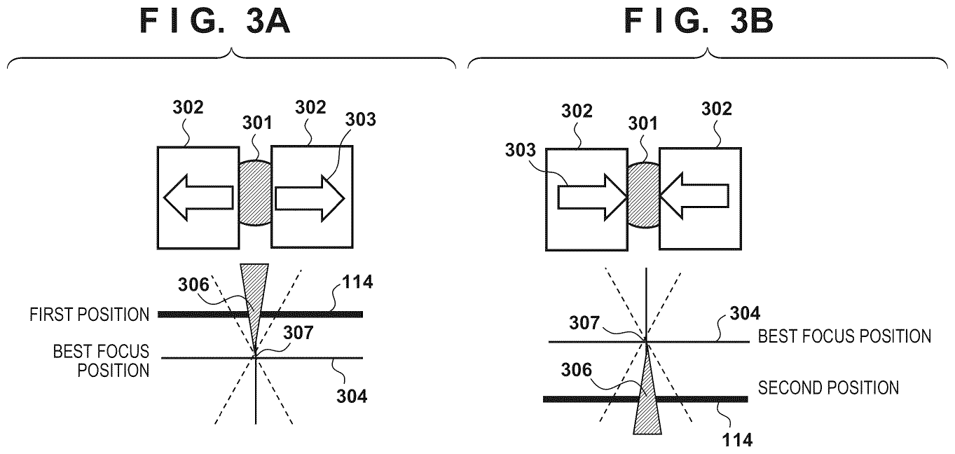

With reference to FIGS. 3A and 3B, the arrangement of the exposure shutter 103 according to the embodiment will be described. The exposure shutter 103 switches blocking and passing of the optical path of exposure light by operating a plurality of light shielding members. The plurality of light shielding members have rotational symmetricity with respect to the optical axis A. The exposure shutter 103 includes a plurality of light shielding members 302. The plurality of light shielding members 302 form a light-passing portion where exposure light passes. The plurality of light shielding members 302 are configured to keep the rotational symmetricity during operation. The plurality of light shielding members 302 include the plurality of light shielding members 302 that are opened and closed in directions indicated by arrows 303 while keeping the symmetricity of the shape of an effective light source 301 with respect to the X-axis and the Y-axis. The exposure shutter driving unit 117 translationally drives each of the plurality of light shielding members 302 in the directions indicated by the arrows 303 under the control of the main controller 130.

In the example shown in FIGS. 3A and 3B, the plurality of light shielding members are two light shielding members. The two light shielding members are arranged at positions which are two-fold rotationally symmetric with respect to the optical axis A. The two light shielding members are translationally driven in opposite directions indicated by the arrows 303.

Here, consider a case in which, to perform multi-focus exposure, the substrate 114 is driven from the first position above a best focus position 304 to the second position below the best focus position 304. FIG. 3A shows a state in which the substrate 114 is at the first position when the exposure shutter 103 is half-open, and FIG. 3B shows a state in which the substrate 114 is at the second position when the exposure shutter 103 is half-closed.

Throughout the opening/closing operation of the exposure shutter 103, the shape of the effective light source 301 keeps the symmetricity with respect to the X-axis and the Y-axis. Accordingly, in the state shown in FIG. 3A in which the substrate 114 is defocused upward when the exposure shutter 103 is half-open, an imaging center 306 in the horizontal direction (X-Y direction) is not deviated from an imaging point 307 of the best focus position 304. Furthermore, in the state shown in FIG. 3B in which the substrate 114 is defocused downward when the exposure shutter 103 is half-closed, the imaging center 306 in the horizontal direction (X-Y direction) is not deviated from the imaging point 307 of the best focus position 304.

In this manner, according to the arrangement shown in FIGS. 3A and 3B, even if the substrate 114 is driven in the optical axis direction of the projection optical system 111, the plurality of light shielding members 302 are driven and the shape of the effective light source 301 changes (defect) while keeping the symmetricity with respect to the X-axis and the Y-axis. In other words, the plurality of light shielding members 302 operate while keeping the rotational symmetricity so exposure light passing through the light-passing portion, which is formed by the plurality of light shielding members 302, is not decentered, regardless of the defocus amount. Therefore, the telecentricity is not lost, and an image shift and a horizontal (vertical) line width difference do not occur.

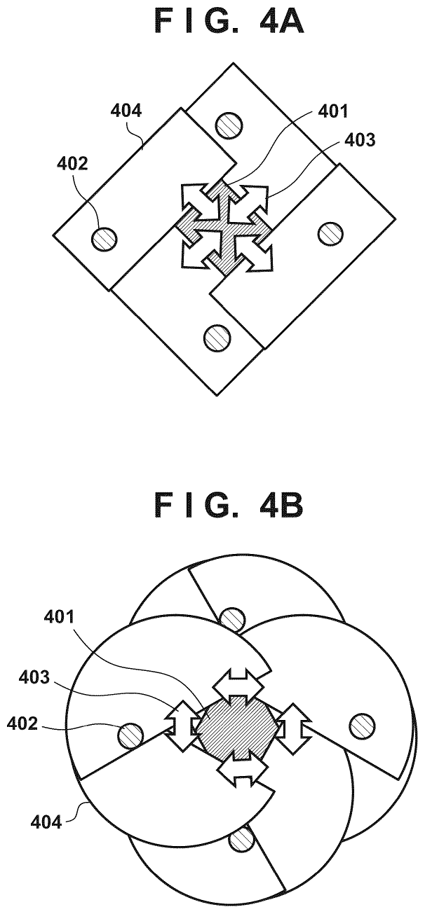

FIG. 4A shows the first modification of the exposure shutter 103. The exposure shutter 103 according to the first modification includes a plurality of light shielding members 404 arranged around the optical axis A. An effective light source 401 is formed by the space serving as a light-passing portion surrounded by the plurality of light shielding members 404. Each of the plurality of light shielding members 404 is supported by a rotation shaft 402 so that it can rotate about the rotation shaft 402. The exposure shutter driving unit 117 rotationally drives each of the plurality of light shielding members 404 under the control of the main controller 130. With this, the plurality of light shielding members 404 respectively move in the directions indicated by arrows 403 such that the shape of the effective light source 301 keeps the symmetricity with respect to the X-axis and the Y-axis. When the plurality of light shielding members 404 are respectively rotationally driven, a shutter opening/closing operation is performed. That is, when the plurality of light shielding members 404 are respectively rotationally driven, the shape of the effective light source 401 is controlled.

FIG. 4B shows the second modification of the exposure shutter 103. Similar to FIG. 4A, the arrangement shown in FIG. 4B includes the plurality of light shielding members 404 arranged around the optical axis A, and the effective light source 401 is formed by the space serving as a light-passing portion surrounded by the plurality of light shielding members 404. In FIG. 4B, a pair of light shielding members share one rotation shaft 402. The pair of light shielding members are rotationally driven about the rotation shaft 402 in opposite directions. That is, the pair of light shielding members perform an opening/closing operation like scissors. With this, the plurality of light shielding members 404 respectively move in the directions indicated by the arrows 403 such that the shape of the effective light source 301 keeps the symmetricity with respect to the X-axis and the Y-axis, and the shape of the effective light source 401 is controlled.

The arrangements shown in FIGS. 4A and 4B, in which the plurality of light shielding members 404 are respectively rotationally driven, are advantageous in that the shutter opening/closing operation can be performed at high speed, as compared to the arrangement shown in FIGS. 3A and 3B in which the light shielding members 302 move translationally.

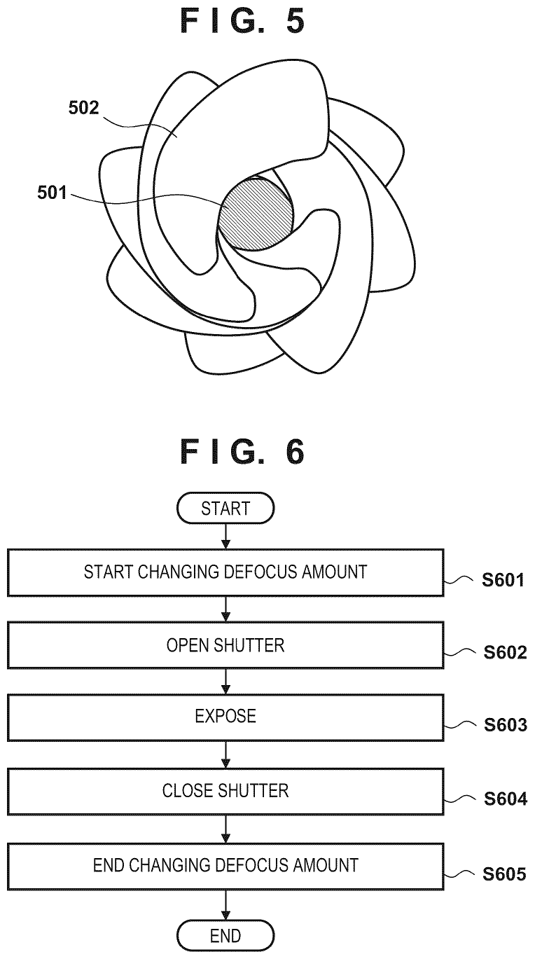

FIG. 5 shows the third modification of the exposure shutter 103. The exposure shutter 103 according to the third modification includes a plurality of light shielding members 502 arranged around the optical axis A. An effective light source 501 is formed by the space serving as a light-passing portion surrounded by the plurality of light shielding members 502. The plurality of light shielding members 502 constitute an iris diaphragm. The iris diaphragm is configured to continuously change the opening diameter concentrically with respect to the optical axis A. By adopting the iris diaphragm configuration, the symmetricity of the effective light source 501 with respect to the X-axis and the Y-axis during the shutter opening/closing operation is kept. Thus, an image shift and a horizontal (vertical) line width difference do not occur. Note that the rotational symmetricity in this embodiment indicates the two-fold or more rotational symmetricity.

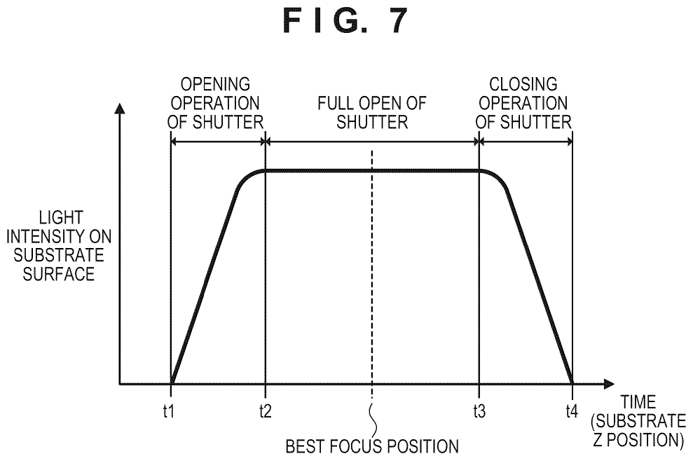

FIG. 6 is a flowchart illustrating an exposure method using multi-focus exposure according to this embodiment. FIG. 7 is a timing chart of the shutter opening/closing operation in multi-focus exposure with respect to one shot region. The exposure method includes the first step of changing the defocus amount in a predetermined range including the best focus position in the optical axis direction of the projection optical system 111. While the defocus amount is changed in the above-described predetermined range, the second step of controlling the exposure shutter 103 is performed. In the second step, the shutter is controlled to transition in the order of a shutter closed state in which the optical path of exposure light is blocked by the plurality of light shielding members, a shutter open state in which the optical path is not blocked by the plurality of light shielding members, and the shutter closed state.

In the example described below, the above-described predetermined range is the range between the first position shown in FIG. 3A and the second position shown in FIG. 3B. In the example described below, multi-focus exposure is performed by driving the substrate 114 from the first position shown in FIG. 3A to the second position shown in FIG. 3B to adjust the defocus amount.

At time t1, the main controller 130 controls the substrate stage driving unit 129 serving as the adjuster to start to change the defocus amount (step S601), and controls the exposure shutter driving unit 117 to start the opening operation of the exposure shutter 103 (step S602). With this, exposure of the shot region on the substrate 114 is started (step S603). In FIG. 7, the abscissa represents time, that is, the Z position of the substrate. The ordinate represents the light intensity on the substrate surface.

At time t2, the exposure shutter 103 is in the full open state. In this state, the Z position of the substrate 114 passes the best focus position, and advances toward the second position shown in FIG. 3B.

At time t3, the main controller 130 controls the exposure shutter driving unit 117 to start the closing operation of the exposure shutter 103 (step S604). At time t4, the exposure shutter 103 is in the full closed state, and the exposure ends. At this timing, the main controller 130 controls the substrate stage driving unit 129 serving as the adjuster to finish changing the defocus amount (step S605).

### <Embodiment of Article Manufacturing Method>

An article manufacturing method of manufacturing an article using the above-described exposure apparatus will be described below. The article manufacturing method can include an exposure step of exposing a substrate using the above-described exposure apparatus or in accordance with the above-described exposure method, a development step of developing the substrate having undergone the exposure step, and a step of obtaining an article from the substrate having undergone the development step. The substrate provided to the exposure apparatus is applied with a photosensitive material (photoresist). In the exposure step, the pattern of the original is transferred as a latent image pattern to the photosensitive material. In the development step, the latent image pattern is converted into a physical device pattern. The step of obtaining the article from the substrate having undergone the development step can include, for example, a step of patterning the underlying layer using the device pattern. Furthermore, the step of obtaining the article from the substrate having undergone the development step may include a step of dicing the substrate.

According to the embodiment described above, a technique advantageous in suppressing occurrence of asymmetry in an effective light source can be provided.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-225567, filed Dec. 20, 2024 which is hereby incorporated by reference herein in its entirety.

What is claimed is:

1. An exposure apparatus that transfers a pattern of an original to a substrate, comprising:
a shutter configured to switch blocking and passing of an optical path of exposure light by operating a plurality of light shielding members;
a projection optical system configured to project a pattern of the original onto the substrate by the exposure light; and
an adjuster configured to adjust a defocus amount which represents a distance between a best focus position in a direction of an optical axis of the projection optical system and a position of a surface of the substrate,
wherein the plurality of light shielding members have rotational symmetricity with respect to the optical axis.

2. The apparatus according to claim 1, wherein the plurality of light shielding members keep the rotational symmetricity during operation.

3. The apparatus according to claim 2, wherein the plurality of light shielding members operate while keeping the rotational symmetricity so exposure light passing through a light-passing portion, which is formed by the plurality of light shielding members, is not decentered, regardless of the defocus amount.

4. The apparatus according to claim 1, wherein
the plurality of light shielding members are two light shielding members,
the two light shielding members are arranged at positions which are two-fold rotationally symmetric with respect to the optical axis, and
the two light shielding members are translationally driven in opposite directions.

5. The apparatus according to claim 1, wherein each of the plurality of light shielding members is rotationally driven.

6. The apparatus according to claim 5, wherein
the plurality of light shielding members include a pair of light shielding members that share one rotation shaft, and
the pair of light shielding members are rotationally driven about the rotation shaft in opposite directions.

7. The apparatus according to claim 1, wherein the shutter includes an iris diaphragm that changes an opening diameter concentrically with respect to the optical axis by driving each of the plurality of light shielding members.

8. The apparatus according to claim 1, further comprising a controller configured to control the shutter and the adjuster,
wherein the controller performs multi-focus exposure in which the substrate is exposed while the adjuster adjusts the substrate to each of a plurality of defocus amounts, and controls an operation of the shutter in the multi-focus exposure.

9. An exposure method of exposing a substrate, comprising:
changing a defocus amount in a predetermined range including a best focus position in a direction of an optical axis of a projection optical system; and
controlling a shutter to transition in an order of a shutter closed state in which an optical path of exposure light is blocked by a plurality of light shielding members, a shutter open state in which the optical path is not blocked by the plurality of light shielding members, and the shutter closed state, while a defocus amount is changed in the predetermined range,
wherein the plurality of light shielding members have rotational symmetricity with respect to the optical axis.

10. An article manufacturing method comprising:
exposing a substrate in accordance with an exposure method defined in claim 9;
developing the substrate exposed in the exposing; and
obtaining an article from the substrate having undergone the developing.
